(19) United States
(12) Patent Application Publication
(10) Pub. No.: US 2026/0058106 A1
(43) Pub. Date: Feb. 26, 2026

(54) SUBSTRATE PROCESSING APPARATUS

(71) Applicant: SAMSUNG ELECTRONICS CO., LTD., Suwon-si (KR)

(72) Inventors: Jisoo Lee, Suwon-si (KR); Sangjine Park, Suwon-si (KR)

(73) Assignee: SAMSUNG ELECTRONICS CO., LTD., Suwon-si (KR)

(21) Appl. No.: 19/048,509

(22) Filed: Feb. 7, 2025

(30) Foreign Application Priority Data
Aug. 22, 2024 (KR) 10-2024-0112883

(51) Int. Cl. H01J 37/32; H01L 21/687

(52) U.S. Cl. CPC H01J 37/32522; H01J 37/32201; H01J 37/32229; H01J 37/3244; H01J 37/32724; H01L 21/68742; H01J 2237/002; H01J 2237/20235; H01J 2237/336

(57) ABSTRACT

A substrate processing apparatus includes a chamber, a heater, a supporting member inside the chamber and configured to support a substrate, the supporting member including a lift pin that is movable in a vertical direction and is configured to move the substrate vertically with respect to the heater, a plasma source configured to excite gas inside the chamber to into a plasma state for an annealing process, and a gas supply member configured to supply gas into the chamber for a substrate processing process.

### CROSS-REFERENCE TO RELATED APPLICATION

This application is based on and claims priority to Korean Patent Application No. 10-2024-0112883, filed on Aug. 22, 2024, in the Korean Intellectual Property Office, the disclosure of which is incorporated by reference in its entirety.

### BACKGROUND

The present disclosure relates to a substrate processing apparatus.

To manufacture a semiconductor device, various processes such as a photolithography, an etching, an ashing, an ion implantation, a thin film deposition, and a cleaning may be performed on a substrate to form a desired pattern. Among these, the etching process is a process of removing a selected irradiation region from the film formed on the substrate, and a wet etching and a dry etching may be used.

Among these, an etching device using a plasma may be used for the dry etching. Typically, to form the plasma, an electromagnetic field is formed in the internal space of the chamber, and the electromagnetic field excites a process gas provided within the chamber into a plasma state.

The plasma refers to an ionized gas state composed of ions, electrons, and radicals. The plasma is created by very high temperatures, strong electric fields, or radiofrequency (RF) electromagnetic fields. The semiconductor device manufacturing process may use the plasma to perform the etching process. The etching process may be performed by a collision of ion particles included in the plasma with the substrate.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate processing apparatus that may be capable of sequentially performing different processes.

Additional aspects will be set forth in part in the description which follows and, in part, will be apparent from the description, or may be learned by practice of the presented embodiments.

According to an aspect of an example embodiment, a substrate processing apparatus may include a chamber, a heater, a supporting member inside the chamber and configured to support a substrate, the supporting member including a lift pin that is movable in a vertical direction and is configured to move the substrate vertically with respect to the heater, a plasma source configured to excite gas inside the chamber to into a plasma state for an annealing process, and a gas supply member configured to supply gas into the chamber for a substrate processing process.

According to an aspect of an example embodiment, a substrate processing apparatus may include a chamber, a heater, a supporting member inside the chamber and configured to support a substrate, the supporting member including a lift pin that is movable ion a vertical direction and I configured to move the substrate vertically with respect to the heater, a purge gas supply member configured to supply a purge gas for an atomic layer etching into the chamber, and a plasma source configured to excite a process gas for an annealing process into a plasma state and supply the process gas excited into the plasma state to the chamber.

According to an aspect of an example embodiment, a substrate processing apparatus may include a chamber, a heater, a supporting member inside the chamber and configured to support a substrate, the supporting member including a lift pin that is movable in a vertical direction and is configured to move the substrate vertically with respect to the heater, a plasma source configured to excite gas inside the chamber to into a plasma state for an annealing process, a precursor supply member configured to supply a precursor gas into the chamber, a reactant supply member configured to supply a reactant gas into the chamber, a process gas supply member configured to supply a process gas for the annealing process into the chamber, a lift pin driving member connected to the lift pin and configured to provide power to move the lift pin in the vertical direction, and a controller configured to control the heater when the process gas is supplied into the chamber and control the lift pin driving member to move an upper end of the lift pin vertically above an upper surface of the supporting member by a predetermined annealing heating height.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a substrate processing apparatus according to one or more embodiments;

FIG. 2 is a diagram illustrating a state in which a refrigerant path is connected to a chiller according to one or more embodiments;

FIG. 3 is a diagram illustrating an upper portion of a lift pin according to one or more embodiments;

FIG. 4 is a top view of a heater according to one or more embodiments;

FIG. 5 is a diagram illustrating a control relationship of a substrate processing apparatus according to one or more embodiments;

FIG. 6 is a timing diagram of an etching process of an atomic layer according to one or more embodiments;

FIG. 7 is a diagram illustrating a substrate processing apparatus during a first period of an etching process of an atomic layer according to one or more embodiments;

FIG. 8 is a diagram illustrating a substrate processing apparatus during a third period of an etching process of an atomic layer according to one or more embodiments;

FIG. 9 is a diagram illustrating a substrate processing apparatus during an annealing process according to one or more embodiments;

FIG. 10 is a diagram illustrating a substrate processing apparatus according to one or more embodiments;

FIG. 11 is a diagram illustrating a substrate processing apparatus according to one or more embodiments;

FIG. 12 is a diagram illustrating a substrate processing apparatus according to one or more embodiments;

FIG. 13 is a diagram illustrating a substrate processing apparatus according to one or more embodiments;

FIG. 14 is a diagram illustrating a substrate processing apparatus according to one or more embodiments; and FIG. 15 is a diagram illustrating a substrate processing apparatus according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

Further, since sizes and thicknesses of constituent members shown in the accompanying drawings are arbitrarily given for better understanding and ease of description, the disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, unless explicitly described to the contrary, the word “comprise”, and variations such as “comprises” or “comprising”, will be understood to imply the inclusion of stated elements but not the exclusion of any other elements.

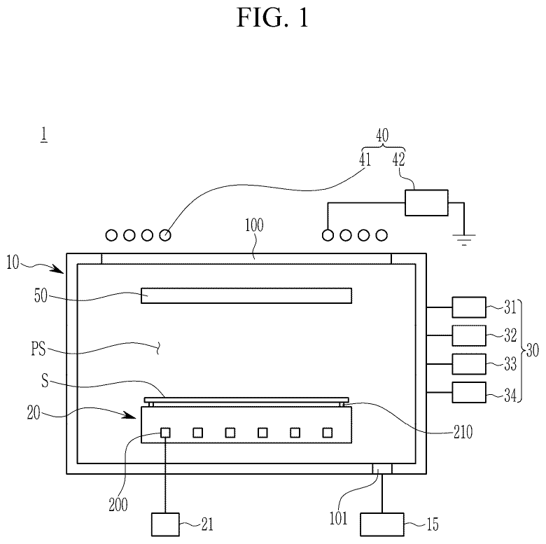

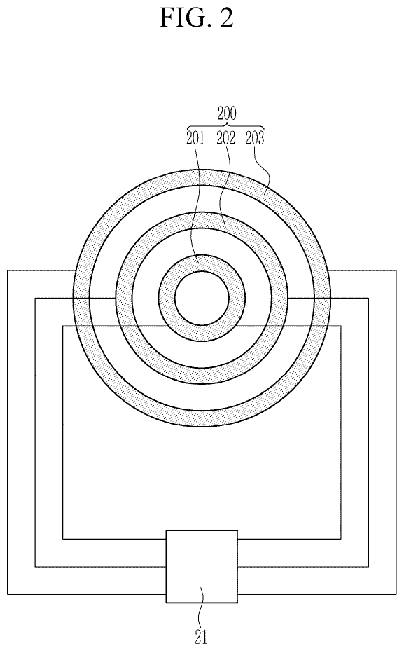

FIG. 1 is a diagram illustrating a substrate processing apparatus according to one or more embodiments.

Referring to FIG. 1, the substrate processing apparatus 1 according to an embodiment may include a chamber 10, a supporting member 20, a gas supply member 30, a plasma source 40, and a heater 50.

The substrate processing apparatus 1 may perform two different processes on a substrate S. The substrate processing apparatus 1 may sequentially perform two different processes on the substrate S. The substrate processing apparatus 1 may perform an etching process and an annealing process on the substrate S. The substrate processing apparatus 1 may perform an atomic layer etching process and a hydrogen plasma annealing process on the substrate S. The substrate S may be a wafer, etc. for manufacturing a semiconductor device.

The chamber 10 may provide a process space PS for processing the substrate S. The chamber 10 may include a metal material. For example, the chamber 10 may include aluminum material, etc. The upper wall 100 of the chamber 10 may have at least some regions including a dielectric material. For example, the upper wall 100 of the chamber 10 may have at least some regions made of quartz or the like to allow electromagnetic waves to pass through.

An exhaust hole 101 may be disposed on one side of the chamber 10. For example, the exhaust hole 101 may be disposed in the lower region of chamber 10. During the treatment process of the substrate S, gases remaining inside chamber 10 after the reaction may be discharged to the outside through the exhaust hole 101. The interior of the chamber 10 may be depressurized to a predetermined pressure by the exhaust process. An exhaust member 15 may be connected to the exhaust hole 101 of the chamber 10. The exhaust member 15 applies a negative pressure for the exhaust to the interior of the chamber 10. Additionally, the exhaust member 15 may control the flow rate of the gas discharged through the exhaust hole 101. The exhaust member 15 may include at least one or more pumps. In addition, the exhaust member 15 may include a valve, etc., so that the flow rate of the gas discharged through the exhaust hole 101 may be controlled according to the shutoff degree of the valve.

The supporting member 20 may be disposed inside the chamber 10. The supporting member 20 may be disposed at the bottom of the process space PS. The supporting member 20 may support the substrate S.

The refrigerant path 200 may be disposed inside the supporting member 20. The refrigerant path 200 may provide a path for the refrigerant to flow within the supporting member 20.

The refrigerant path 200 may be connected to the chiller 21. The chiller 21 may supply the refrigerant to the refrigerant path 200 and recover the refrigerant from the refrigerant path 200. Accordingly, the refrigerant may be circulated between the refrigerant path 200 and the chiller 21.

The refrigerant may flow through the refrigerant path 200 and cool the refrigerant path 200 and the supporting member 20. As the supporting member 20 is cooled, the substrate S positioned on the supporting member 20 may be cooled.

FIG. 2 is a diagram illustrating a state in which a refrigerant path is connected to a chiller according to one or more embodiments.

Referring to FIG. 2, the refrigerant path 200 may include a plurality of sub-refrigerant paths 201, 202, and 203 that are spaced apart or separated from each other. For example, the plurality of sub-refrigerant paths 201, 202, and 203 may be arranged to form a concentric circle with different radii.

The plurality of sub-refrigerant paths 201, 202, and 203 may each be connected to the chiller 21. The chiller 21 may individually supply the refrigerant to each of the sub-refrigerant paths 201, 202, and 203, and individually recover the refrigerant from each of the sub-refrigerant paths 201, 202, and 203. Accordingly, the temperature of each sub-refrigerant path 201, 202, and 203 may be individually controlled. Depending on the temperature control of the sub-refrigerant paths 201, 202, and 203, the temperature of the supporting member 20 may be controlled for each region.

FIG. 2 illustrates an example where the refrigerant path 200 includes a first sub-refrigerant path 201, a second sub-refrigerant path 202, and a third sub-refrigerant path 203. The second sub-refrigerant path 202 may be disposed at the outer circumference of the first sub-refrigerant path 201. The third sub-refrigerant path 203 may be disposed at the outer circumference of the second sub-refrigerant path 202. The number of the sub-refrigerant paths 201, 202, and 203 is exemplary, and the number of the sub-refrigerant paths 201, 202, and 203 may be increased or decreased.

Referring to FIG. 1, the supporting member 20 may include a lift pin 210. A plurality of lift pins 210 may be provided. The plurality of lift pins 210 may be spaced apart from each other on a circle with respect to the center of the supporting member 20. The lift pin 210 may be moved in the vertical direction. As the lift pin 210 rises, the upper portion of the lift pin 210 may protrude upwards and be spaced apart from the upper surface of the supporting member 20. That is, the lift pin 210 may include an upper portion that is exposed above the upper surface of the supporting member 20. As the lift pin 210 moves vertically upward, the upper portion of the lift pin 210 may become more vertically spaced apart from the upper surface of the supporting member 20. In one or more embodiments, the upper portion of the lift pin 210 is completely recessed within the supporting member 20 when it is not moved vertically upward. In one or more embodiments, such as that shown in FIG. 1, in a neural state, the lift pin 210 includes an upper portion that protrudes from the upper surface of the supporting member 20, and a lower portion that is contained within the supporting member 20. Various configurations of the lift pin 210 with respect to the supporting member 20 may be implemented without departing from the scope of the disclosure, as will be understood by one of ordinary skill in the art.

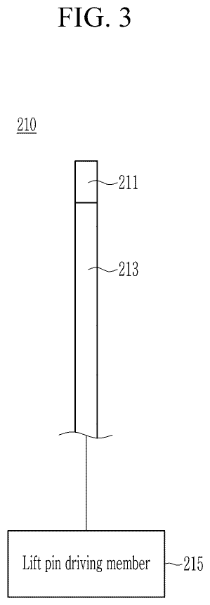

FIG. 3 is a diagram illustrating an upper portion of a lift pin according to one or more embodiments.

Referring to FIG. 3, the lift pin 210 may include an upper portion and a lower portion 213. The upper portion may be an insulation layer 211. Accordingly, when the substrate S is positioned on the lift pin 210, the insulation layer 211 may come into contact with the substrate S. The insulation layer 211 can block or minimize heat transfer between the substrate S and the lift pin 210. The lower portion 213 may be recessed within the supporting member 20, and the vertical movement of the lift pin 210 may be controlled via a lift pin driving member 215 described later.

Referring to FIG. 1, the gas supply member 30 may be connected to the chamber 10. The gas supply member 30 may supply a gas to be used in the processing process of the substrate S into the interior of the chamber 10. The gas supply member 30 may include a precursor supply member 31, a reactant supply member 32, a purge gas supply member 33, and a process gas supply member 34.

The precursor supply member 31 may be connected to chamber 10. The precursor supply member 31 may supply a precursor gas into the interior of chamber 10. The precursor supply member 31 may include a tank for storing a precursor gas, a valve for turning the supply of precursor gas on and off, etc. The precursor gas may react with the surface of the substrate S to form a modified layer. The precursor gas may be a gas including at least one of a halogen group element gas, a halogen group element-including compound, and a combination thereof. The halogen group element may be BCl₃, Cl₂, CF₄, C₄F₈, SF₆. The halogen group element including compound may be a compound including at least one halogen group element. Additionally, the precursor gas may further include a gas including at least one of O₂, H₂, He, N₂, Ar and a combination thereof.

Additionally, the precursor supply member 31 may selectively supply two or more precursor gases into the interior of the chamber 10. For this purpose, the precursor supply member 31 may include two or more storage tanks, and each storage tank may be connected in parallel to the chamber 10.

The reactant supply member 32 may be connected to the chamber 10. The reactant supply member 32 may supply the reactant gas into the interior of the chamber 10. The reactant supply member 32 may include a tank for storing the reactant gas and a valve for turning the supply of the reactant gas on and off, etc. The reactant gas may remove the modified layer from the substrate S. The reactant gas may be argon, etc.

Additionally, the reactant supply member 32 may selectively supply two or more reactant gases into the interior of chamber 10. For this purpose, the reactant supply member 32 may include two or more storage tanks, and, each storage tank may be connected in parallel to the chamber 10.

The purge gas supply member 33 may be connected to the chamber 10. The purge gas supply member 33 may supply a purge gas into the interior of chamber 10. The purge gas supply member 33 may include a tank for storing the purge gas, a valve for turning the supply of the purge gas on and off, etc. The purge gas may be an inert gas. For example, the purge gas may be a gas including at least one of nitrogen, argon, neon, helium, and a combination thereof.

The process gas supply member 34 may be connected to the chamber 10. The process gas supply member 34 may supply a process gas for the annealing process. The process gas supply member 34 may include a tank for storing the process gas, a valve for turning the supply of the process gas on and off, etc. The process gas may include a hydrogen gas.

The plasma source 40 may excite the gas into a plasma state inside the chamber 10. The plasma source 40 may include a plasma excite member 41 and a source power supply 42.

The plasma excite member 41 may provide an energy for a plasma excitation inside the chamber 10. The plasma excite member 41 may have an antenna structure. For example, the plasma excite member 41 may be provided in a ring shape, an arc shape, etc. Additionally, the plasma excite member 41 may have a spirally wound structure and may be disposed on at least two planes that are in the same plane or at different heights.

The plasma excite member 41 may be disposed outside the chamber 10. The plasma excite member 41 may be disposed adjacent to the upper surface of the upper wall 100 of the chamber 10. The plasma excite member 41 may be disposed to face the interior space of the chamber 10 with the upper wall 100 of the chamber 10 therebetween.

The source power supply 42 may provide an electric power for the plasma excitation. The source power supply 42 may be electrically connected to the plasma excite member 41. The source power supply 42 may include a high frequency power source that generates high frequency electric power. The source power supply 42 may include a radiofrequency (RF) power source. The plasma excite member 41 may generate electromagnetic waves through the electric power provided by the source power supply 42. The gas supplied into the interior of the chamber 10 may be excited into plasma by the electromagnetic waves generated from plasma excite member 41.

The heater 50 may heat the interior of the chamber 10. The heater 50 may heat the supporting member 20. Accordingly, when the substrate S is positioned on the supporting member 20, the heater 50 may heat the substrate S positioned on the supporting member 20. The heater 50 may be disposed inside the chamber 10. The heater 50 may be disposed above the supporting member 20. The heater 50 may be disposed to face the supporting member 20 in the vertical direction. The heater 50 may be a light emitting diode (LED) lamp, an infrared (IR) lamp, a laser irradiation module, a microwave irradiation module, etc. The heater 50 may heat the substrate S positioned on the supporting member 20 by emitting heat via a heat energy source toward the supporting member 20. The heat energy source may be light, microwave, etc. emitted by the heater 50.

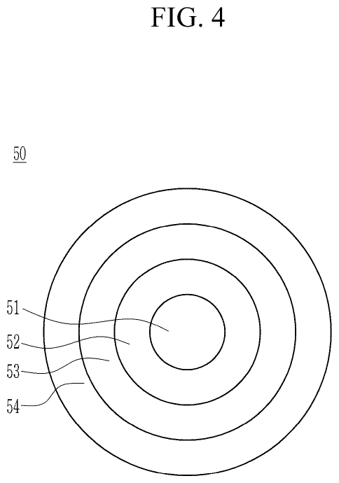

FIG. 4 is a top view of a heater according to one or more embodiments.

Referring to FIG. 4, the heater 50 may include a plurality of sub-heaters 51, 52, 53, and 54 that are partitioned from or spaced apart from each other. For example, the plurality of sub-heaters 51, 52, 53, and 54 may be arranged to form a concentric circle with different radii. The plurality of sub-heaters 51, 52, 53, and 54 may each provide a thermal energy source toward the region positioned below.

Each of the sub-heaters 51, 52, 53, and 54 may be individually turned on and off. Additionally, each of the sub-heaters 51, 52, 53, and 54 may be individually adjusted to provide the intensity of the heat energy directed toward the supporting member 20.

FIG. 4 illustrates an example where the heater 50 includes a first sub-heater 51, a second sub-heater 52, a third sub-heater 53, and a fourth sub-heater 54. The second sub-heater 52 may be disposed at the outer circumference of the first sub-heater 51. The third sub-heater 53 may be disposed at the outer circumference of the second sub-heater 52. The fourth sub-heater 54 may be disposed at the outer circumference of the third sub-heater 53. The number of the sub-heaters 51, 52, 53, and 54 is exemplary, and the number of the sub-heaters 51, 52, 53, and 54 may be increased or decreased.

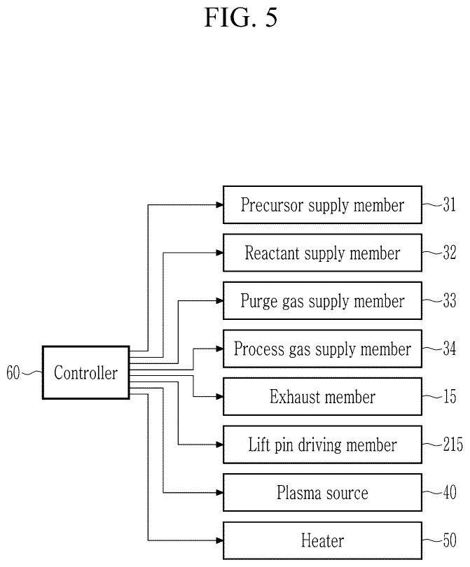

FIG. 5 is a diagram illustrating a control relationship of a substrate processing apparatus according to one or more embodiments.

Referring to FIG. 5, the controller 60 may control the operation of components of the substrate processing apparatus 1.

The controller 60 may control the precursor supply member 31 to control the supply of the precursor gas into the interior of the chamber 10. The controller 60 may control the timing at which the supply of precursor gas into the interior of the chamber 10 begins by controlling the precursor supply member 31. The controller 60 may control the timing at which the supply of the precursor gas into the inside of the chamber 10 ends by controlling the precursor supply member 31. The controller 60 may control the flow rate of the precursor gas supplied into the inside of the chamber 10 by controlling the precursor supply member 31.

The controller 60 may control the reactant supply member 32 to control the supply of the reactant gas into the inside of the chamber 10. The controller 60 may control the timing at which the supply of the reactant gas into the inside of the chamber 10 begins by controlling the reactant supply member 32. The controller 60 may control the timing at which the supply of the reactant gas into the inside of the chamber 10 ends by controlling the reactant supply member 32. The controller 60 may control the flow rate of the reactant gas supplied into the inside of the chamber 10 by controlling the reactant supply member 32.

The controller 60 may control the purge gas supply member 33 to control the supply of the purge gas into the interior of the chamber 10. The controller 60 may control the timing at which the supply of the purge gas into the inside of the chamber 10 begins by controlling the purge gas supply member 33. The controller 60 may control the timing at which the supply of the purge gas into the inside of the chamber 10 ends by controlling the purge gas supply member 33. The controller 60 may control the flow rate of the purge gas supplied into the inside of the chamber 10 by controlling purge gas supply member 33.

The controller 60 may control the process gas supply member 34 to control the state in which the process gas is supplied to the interior of the chamber 10. The controller 60 may control the timing at which the supply of the process gas into the interior of the chamber 10 begins by controlling the process gas supply member 34. The controller 60 may control the timing at which the supply of the process gas to the interior of the chamber 10 ends by controlling the process gas supply member 34. The controller 60 may control the flow rate of the process gas supplied into the inside of the chamber 10 by controlling the process gas supply member 34.

The controller 60 may control the exhaust member 15 to adjust the exhaust state for the inside of the chamber 10. Additionally, the controller 60 may control the exhaust member 15 to regulate the pressure inside the chamber 10. The controller 60 may control the exhaust member 15, thereby controlling the timing at which the exhaust begins for the inside of the chamber 10. The controller 60 may control the exhaust member 15, thereby controlling the timing at which the exhaust ends for the inside of the chamber 10. The controller 60 may control the exhaust member 15 to control the flow rate of the gas exhausted inside the chamber 10.

The controller 60 may control the vertical direction movement status of the lift pin 210 by controlling a lift pin driving member 215. The lift pin driving member 215 may be connected to the lift pin 210 and may provide a power to move the lift pin 210 in the vertical direction. The lift pin driving member 215 may be connected to the lower end of the lift pin 210. The lift pin driving member 215 may be disposed at the lower side of the supporting member 20 (e.g., housed within the supporting member 20). The lift pin driving member 215 may be a motor, a hydraulic pressure cylinder, etc. The controller 60 may control the lift pin driving member 215 to lift the lift pin 210. The controller 60 may control the lift pin driving member 215 to lower the lift pin 210. The controller 60 may control the lift pin driving member 215 to stop the lift pin 210 with the upper end of the lift pin 210 positioned at a predetermined height.

The controller 60 may control the plasma source 40 to control the state of the plasma excited inside the chamber 10. The controller 60 may control the plasma source 40 to control the timing at which the plasma excitation begins inside the chamber 10. The controller 60 may control the plasma source 40 to control the timing at which the plasma excitation ends inside the chamber 10. The controller 60 may control the plasma source 40 to adjust the magnitude of the energy applied for the excite plasma inside the chamber 10.

The controller 60 may control the timing at which the source power supply 42 starts the supplying electric power, thereby controlling the timing at which the plasma excitation begins inside the chamber 10. The controller 60 may control the timing when the source power supply 42 terminates the electric power supply, thereby controlling the timing when the plasma excitation inside the chamber 10 ends. The controller 60 may control the magnitude of the electric power supplied by the source power supply 42, thereby controlling the magnitude of the energy applied to excite the plasma inside the chamber 10.

The controller 60 may control the heater 50 to control the heating state of the substrate S positioned on the supporting member 20. The controller 60 may control the timing at which the heater 50 begins irradiating the heat energy source toward the supporting member 20, thereby controlling the timing at which the heating for the substrate S positioned on the supporting member 20 by the heater 50 begins. The controller 60 may control the timing at which the heater 50 ends providing the heat energy source toward the supporting member 20, thereby controlling the timing at which the heating for the substrate S positioned on the supporting member 20 by the heater 50 ends. The controller 60 may control the intensity of the heat energy source that the heater 50 provides toward the supporting member 20, thereby controlling the temperature at which the substrate S positioned on the supporting member 20 is heated by the heater 50.

The controller 60 may individually control the on/off state of the plurality of sub-heaters 51, 52, 53, and 54. The controller 60 may be capable of individually controlling the intensity of the thermal energy source irradiated towards the supporting member 20 by the plurality of sub-heaters 51, 52, 53, and 54.

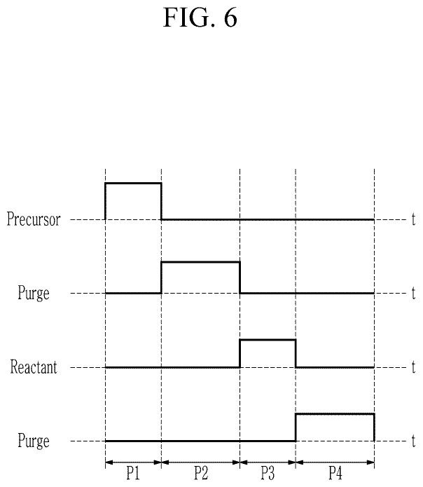

FIG. 6 is a timing diagram of an etching process of an atomic layer according to one or more embodiments.

Referring to FIG. 6, a process of performing an atomic layer etching process for 1 cycle is described.

First, the precursor supply member 31 may supply the precursor gas into the interior of the chamber 10. The precursor supply member 31 may supply the precursor gas during a first period P1. Accordingly, the precursor gas may react with the surface of the substrate S, thereby forming a modified layer. The precursor gas may react with the surface of substrate S in a self-limiting reaction form.

Afterwards, the purge gas supply member 33 may supply the purge gas into the interior of the chamber 10. The purge gas supply member 33 may supply the purge gas during a second period P2. For example, the second period P2 may start after the first period P1 ends. The end of the first period P1 and the start of the second period P2 may occur simultaneously. When the purge gas is supplied, the exhaust member 15 may perform the exhaust for the interior of the chamber 10. Accordingly, the precursor gas remaining after the reaction may be removed inside the chamber 10.

Afterwards, the reactant supply member 32 may supply the reactant gas into the interior of the chamber 10. The reactant supply member 32 may supply the reactant gas during a third period P3. For example, the third period P3 may start after the second period P2 ends. The end of the second period P2 and the start of the third period P3 may occur simultaneously. The reactant gas may react with the modified layer and remove the modified layer from the substrate S. As the modified layer is removed from the substrate S, an etching process may be performed on the substrate S.

Afterwards, the purge gas supply member 33 may supply the purge gas into the interior of the chamber 10. The purge gas supply member 33 may supply the purge gas during a fourth period P4. For example, the fourth period P4 may start after the third period P3 ends. The end of the third period P3 and the start of the fourth period P4 may occur simultaneously. When the purge gas is supplied, the exhaust member 15 may perform the exhaust for the interior of the chamber 10. Accordingly, the reactant gas remaining after the reaction may be removed inside the chamber 10.

The atomic layer etching process may be performed by repeating one cycle, or at least two or more cycles. If two or more cycles are repeated, the next cycle may begin when one cycle ends. The first period P1 of the next cycle may start after the fourth period P4 of the previous cycle ends. The beginning of the first period P1 of the next cycle and the end of the fourth period P4 of the previous cycle may occur simultaneously.

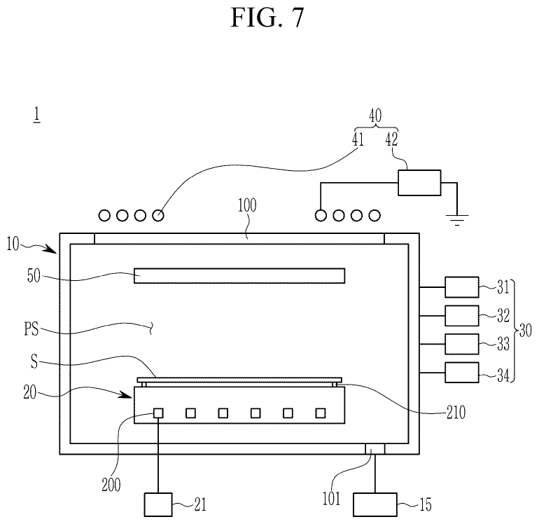

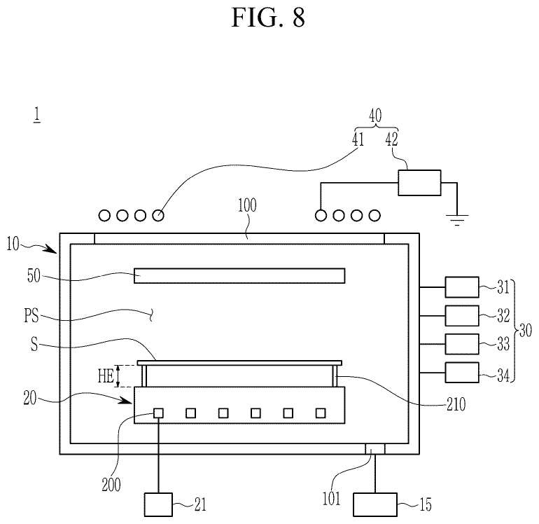

FIG. 7 is a diagram illustrating a substrate processing apparatus during a first period P1 of an etching process of an atomic layer according to one or more embodiments. FIG. 8 is a diagram illustrating a substrate processing apparatus during a third period P3 of an etching process of an atomic layer according to one or more embodiments.

Referring to FIG. 7 and FIG. 8, the substrate processing apparatus 1 may be operated so that the temperature of the substrate S is higher during the third period P3 than during the first period P1. For example, during the first period P1, the substrate processing apparatus 1 may be operated so that the temperature of the substrate S is between about −50°C and 50° C. Also, during the third period P3, the substrate processing apparatus 1 may be operated so that the temperature of the substrate S is between about 200° C. to 500° C.

Accordingly, the controller 60 may control the heater 50 so that the intensity of the heat energy source provided to the substrate S is greater during the third period P3 than during the first period P1. For example, the controller 60 may turn off the heater 50 during the first period P1 and turn on the heater 50 during the third period P3. Additionally, the controller 60 may control the heater 50 so that the heater 50 is turned on in the first period P1 and the third period P3, and the intensity of the heat energy source of the heater 50 in the third period P3 is greater than the intensity of the heat energy source of the heater 50 in the first period P1.

Additionally, the controller 60 may control the temperature of the substrate S by varying the distance between the substrate S and the heater 50 in the first period P1 and the third period P3. That is, the substrate processing apparatus 1 may be operated so that the distance between the substrate S and the heater 50 becomes shorter during the third period P3 than during the first period P1. To this end, during the third period P3, the controller 60 may control the lift pin driving member 215 so that the upper end of the lift pin 210 is positioned above the upper surface of the supporting member 20 by an etching heating height HE. Accordingly, during the third period P3, the lower surface of the substrate S may be positioned above the upper surface of the supporting member 20 by the etching heating height HE. In the third period P3, the heater 50 may be the turned on state. Also, during the first period P1, the controller 60 may control the lift pin driving member 215 to position the upper end of the lift pin 210 to be lower than the etching heating height HE. For example, during the first period is P1, the upper end of the lift pin 210 may be positioned at a coplanar height with the upper surface of the supporting member 20 or below the upper surface of the supporting member 20, so that the substrate S may be positioned on the upper surface of the supporting member 20. During the first period P1, the heater 50 may be the turned on or off state.

During the first period P1, the refrigerant may be circulating in the refrigerant path 200 of the supporting member 20. During the first period is P1, the temperature of the substrate S may be controlled through the distance between the supporting member 20, which is cooled by the refrigerant, and the substrate S. That is, during the first period is P1, the temperature of the substrate S may be controlled by controlling the distance between the supporting member 20, which is cooled by the refrigerant, and the substrate S, as well as controlling the distance between the heater 50 and the substrate S.

Additionally, during the third period is P3, the refrigerant may be circulating in the refrigerant path 200 of the supporting member 20. During the third period is P3, the temperature of the substrate S may be controlled by controlling the distance between the supporting member 20, which is cooled by the refrigerant, and the substrate S. That is, during the third period is P3, the temperature of the substrate S may be controlled by controlling the distance between the supporting member 20, which is cooled by the refrigerant and the substrate S, and the distance between the heater 50 and the substrate S.

During the first period P1, the controller 60 may operate the plasma source 40. Accordingly, the precursor gas may react with the substrate S after being excited into a plasma state.

During the third period is P3, the controller 60 may operate the plasma source 40. Accordingly, the reactant gas may act on the modified layer formed on the substrate S after being excited in a plasma state.

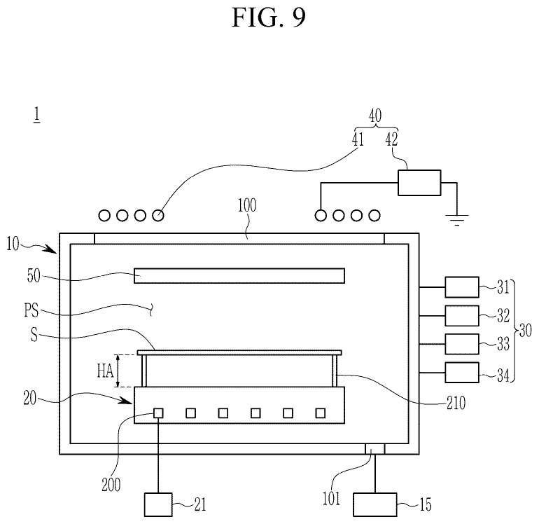

FIG. 9 is a diagram illustrating a substrate processing apparatus during an annealing process according to one or more embodiments.

Referring to FIG. 9, the substrate processing apparatus 1 may perform an annealing process after the etching process. As the annealing process is performed after the etching process, defects on the surface of the substrate S or the surface of the pattern formed on the substrate S may be cured or the roughness may be reduced.

The substrate processing apparatus 1 may be operated so that the annealing process is performed at the temperature of the substrate S of about 400° C. to 600° C. For example, the substrate processing apparatus 1 may be operated so that the temperature of the substrate S is higher during the annealing process than during the etching process of the atomic layer.

When the etching process, which includes at least one cycle, is completed, the annealing process may begin. When the annealing process starts, the controller 60 may control the process gas supply member 34 to supply the process gas into the interior of the chamber 10. Additionally, the controller 60 may operate the plasma source 40. Accordingly, the process gas supplied into the interior of the chamber 10 may be excited into a plasma state. Additionally, the controller 60 may turn on the heater 50 so that a heat energy source for heating is provided to the substrate S. Additionally, the controller 60 may control the lift pin driving member 215 so that the upper end of the lift pin 210 is positioned above the upper surface of the supporting member 20 by an annealing heating height HA. Accordingly, during the annealing process, the lower surface of the substrate S may be positioned above (e.g., separated from) the upper surface of the supporting member 20 by the annealing heating height HA. Accordingly, the distance between the substrate S and the heater 50 may become shorter than when the substrate S is positioned on the upper surface of the supporting member 20, so the substrate S may be heated effectively. The annealing heating height HA may be greater than the etching heating height HE. Accordingly, the temperature of the substrate S may be higher during the annealing process than during the etching process.

According to an embodiment, the substrate processing apparatus 1 may sequentially perform the etching process and the annealing process after the substrate S is introduced into the chamber 10. Compared to the etching process, the annealing process needs to be performed at high temperature. While the substrate processing apparatus 1 raises the substrate S toward the heater 50 by the annealing heating height HA during the annealing process, the heater 50 heats the substrate S. Accordingly, the substrate processing apparatus 1 may effectively perform the etching process and the annealing process within one chamber 10 without having to remove the substrate S from the chamber 10.

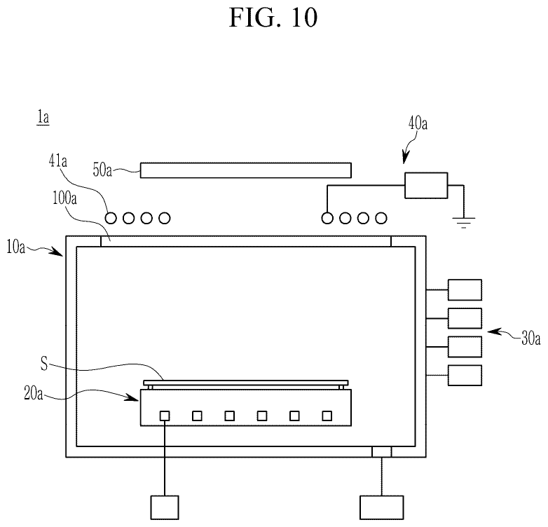

FIG. 10 is a diagram illustrating a substrate processing apparatus according to one or more embodiments.

Referring to FIG. 10, a substrate processing apparatus 1a according to one or more embodiments may include a chamber 10a, a supporting member 20a, a gas supply member 30a, a plasma source 40a, and a heater 50a.

The substrate processing apparatus 1a may perform two different processes on the substrate S. The substrate processing apparatus 1a may sequentially perform two different processes on the substrate S. The substrate processing apparatus 1a may perform the etching process and the annealing process on the substrate S. The substrate processing apparatus 1a may perform an atomic layer etching process and a hydrogen plasma annealing process on the substrate S.

The heater 50a may be disposed outside the chamber 10a. The heater 50a may be disposed to face the upper wall 100a of the chamber 10a in the vertical direction. The upper wall 100a of the chamber 10a may have at least some regions that include a dielectric material. For example, the upper wall 100a of the chamber 10a may have at least some regions made of quartz, etc. Accordingly, the upper wall 100a of the chamber 10a may transmit the heat energy source provided by the heater 50a. The heater 50a may be disposed above the plasma excite member 41a.

The remaining structure of the substrate processing apparatus 1a and the control of the substrate processing apparatus 1a are the same as or similar to those described above, and thus repeated descriptions are omitted.

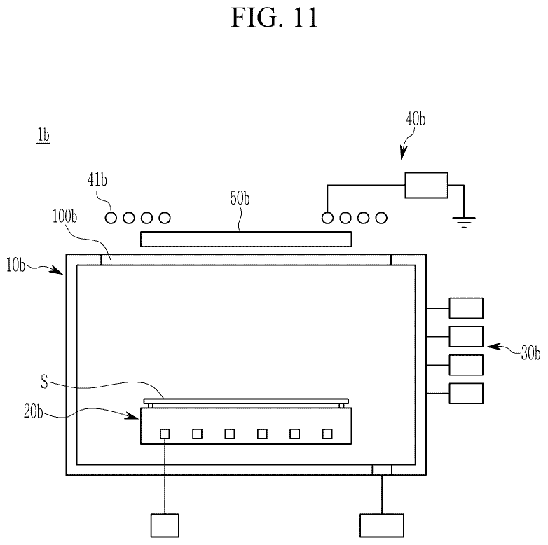

FIG. 11 is a diagram illustrating a substrate processing apparatus according to one or more embodiments.

Referring to FIG. 11, a substrate processing apparatus 1b according to one or more embodiments may include a chamber 10b, a supporting member 20b, a gas supply member 30b, a plasma source 40b, and a heater 50b.

The substrate processing apparatus 1b may perform two different processes on the substrate S. The substrate processing apparatus 1b may sequentially perform two different processes on the substrate S. The substrate processing apparatus 1b may perform an etching process and annealing process on the substrate S. The substrate processing apparatus 1b may perform an atomic layer etching process and a hydrogen plasma annealing process on the substrate S.

The heater 50b may be disposed outside the chamber 10b. The heater 50b may be disposed to face the upper wall 100b of the chamber 10b in the vertical direction. The upper wall 100b of the chamber 10b may have at least some regions that include a dielectric material. For example, the upper wall 100b of the chamber 10b may have at least some regions made of quartz, etc. Accordingly, the upper wall 100b of the chamber 10b may be permeable to the heat energy source provided by the heater 50b. The heater 50b may be disposed below the plasma excite member 41b. The heater 50b may be disposed between the plasma excite member 41b and the upper wall 100b of the chamber 10b.

The remaining structure of the substrate processing apparatus 1b and the control of the substrate processing apparatus 1b are the same as or similar to those described above, and thus repeated descriptions are omitted.

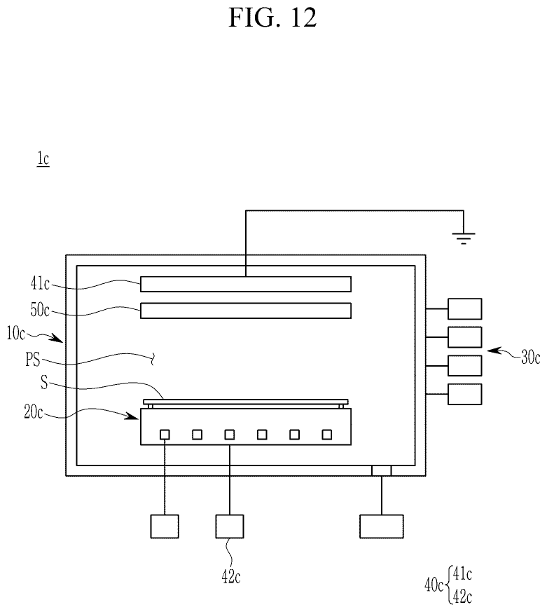

FIG. 12 is a diagram illustrating a substrate processing apparatus according to one or more embodiments.

Referring to FIG. 12, a substrate processing apparatus 1c according to one or more embodiments may include a chamber 10c, a supporting member 20c, a gas supply member 30c, a plasma source 40c, and a heater 50c.

The substrate processing apparatus 1c may perform two different processes on the substrate S. The substrate processing apparatus 1c may sequentially perform two different processes on the substrate S. The substrate processing apparatus 1c may perform an etching process and annealing process on the substrate S. The substrate processing apparatus 1c may perform an atomic layer etching process and a hydrogen plasma annealing process on the substrate S.

The plasma source 40c may excite gas into a plasma state inside the chamber 10c. The plasma source 40c may include a plasma excite member 41c and a source power supply 42c.

The plasma excite member 41c may provide an energy for the plasma excitation in the process space PS. The plasma excite member 41c may be provided so that the lower surface of thereof faces the interior of the chamber 10c. For example, the plasma excite member 41c may be disposed inside the chamber 10c. The plasma excite member 41c may be manufactured separately from the chamber 10c and be connected to the chamber 10c. Alternatively, the plasma excite member 41c may be provided integrally with the upper structure of the chamber 10c. That is, the upper structure of the chamber 10c may function as the plasma excite member 41c.

The plasma excite member 41c may be disposed at the upper portion of the process space PS. The plasma excite member 41c may be include a conductive material in a predetermined area. The plasma excite member 41c may be disposed to face the supporting member 20c in the vertical direction.

The source power supply 42c may provide an electric power for the plasma excitation. The source power supply 42c may be electrically connected to the supporting member 20c. The source power supply 42c may be electrically connected to the region provided with a conductive material in the supporting member 20c. Additionally, the source power supply 42c may be electrically connected to the plasma excite member 41c. The source power supply 42c may include a high frequency power source that generates high frequency electric power. The source power supply 42c may include a RF power.

The gas inflowing into the chamber 10c may be excited into plasma by an electric field formed inside the chamber 10c. Specifically, the process gas may be excited into a plasma by a capacitively coupled plasma (CCP) method. The CCP method may include an upper electrode and a lower electrode. The upper electrode and the lower electrode may be placed vertically facing each other inside the chamber 10c. By applying a high-frequency electric power to at least one of the upper electrode and the lower electrode, an electromagnetic field may be formed in the space between the upper electrode and the lower electrode, and the gas supplied to this space may be excited into a plasma state. The upper electrode may be the plasma excite member 41c, and the lower electrode may be the supporting member 20c. A high-frequency power may be connected to only one of the upper and lower electrodes. For example, the upper electrode may be grounded, and only the lower electrode may be powered by a high-frequency power. Additionally, the lower electrode may be grounded, and only the upper electrode may be connected to a high-frequency power. Additionally, a high frequency power may be connected to both the upper and lower electrodes. FIG. 12 illustrates an example where a high-frequency power source is connected to the lower electrode.

The heater 50c may be disposed inside the chamber 10c. The heater 50c may be disposed below the plasma excite member 41c. The heater 50c may be disposed between the plasma excite member 41c and the supporting member 20c.

The remaining structure of the substrate processing apparatus 1c and the control of the substrate processing apparatus 1c are the same as or similar to those described above, and thus repeated descriptions are omitted.

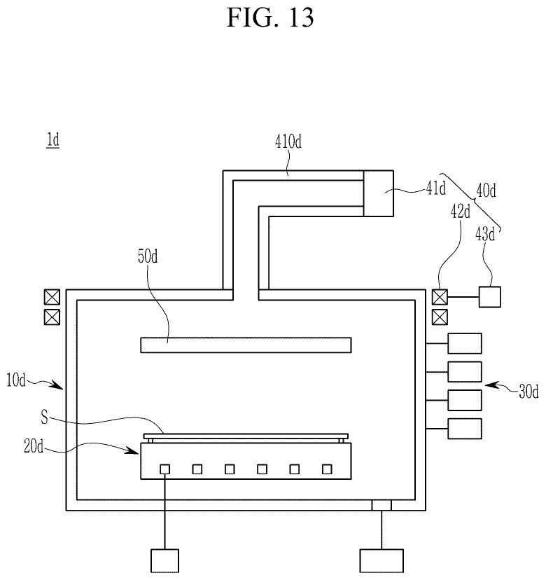

FIG. 13 is a diagram illustrating a substrate processing apparatus according to one or more embodiments.

Referring to FIG. 13, a substrate processing apparatus 1d according to one or more embodiments may include a chamber 10d, a supporting member 20d, a gas supply member 30d, a plasma source 40d and a heater 50d.

The substrate processing apparatus 1d may perform two different processes on substrate S. The substrate processing apparatus 1d may sequentially perform two different processes on the substrate S. The substrate processing apparatus 1d may perform an etching process and an annealing process on the substrate S. The substrate processing apparatus 1d may perform an atomic layer etching process and a hydrogen plasma annealing process on substrate S.

The plasma source 40d may excite the gas into a plasma state inside the chamber 10d. The plasma source 40d may include a magnetron 41d, an electron coil 42d, and a source power supply 43d.

The magnetron 41d generates microwaves. The magnetron 41d may be connected to the chamber 10d via a waveguide 410d. Microwaves generated in the magnetron 41d may travel through the waveguide 410d and then be transmitted into the interior of the chamber 10d.

The electron coil 42d may be disposed at the outer circumference of the chamber 10d. The electron coil 42d may be disposed at the outer circumference of the upper portion of the chamber 10d. The chamber 10d may include a dielectric material provided at at least a portion of the region facing the electron coil 42d. As an example, the chamber 10d may have at least a portion of the region facing the electron coil 42d made of quartz or the like.

The source power supply 43d may be electrically connected to the electron coil 42d. The source power supply 43d may provide a magnetic field by the electron coil 42d inside the chamber 10d and an electric power for an electron cyclotron resonance plasma excitation. The source power supply 43d may include a high frequency power source that generates a high frequency electric power. The source power supply 43d may include an RF power source. The electron coil 42d may generate a magnetic field through an electric power provided by the source power supply 43d. The gas supplied into the interior of the chamber 10d may be excited into plasma by the resonance of microwave and magnetic fields.

The remaining structure of the substrate processing apparatus 1d and the control of the substrate processing apparatus 1d are the same as or similar to those described above, and thus repeated descriptions are omitted.

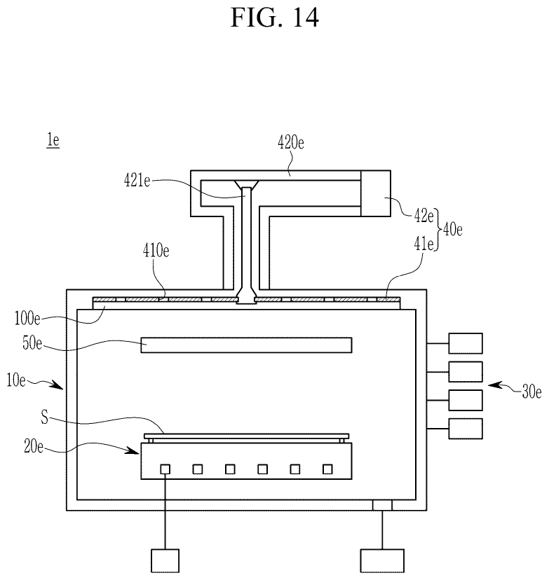

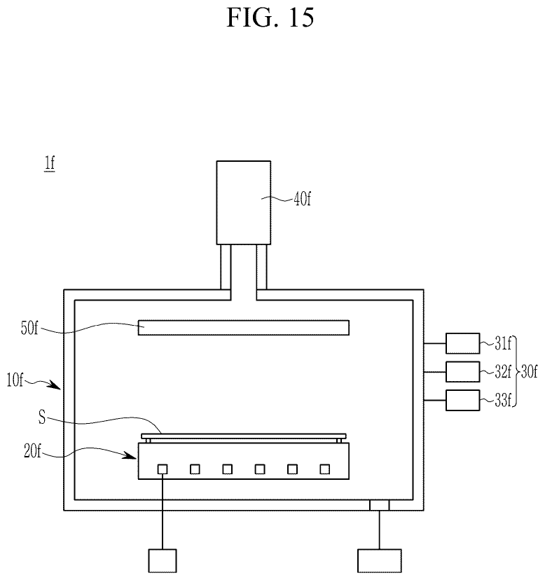

FIG. 14 is a diagram illustrating a substrate processing apparatus according to one or more embodiments.

Referring to FIG. 14, a substrate processing apparatus 1e according to one or more embodiments may include a chamber 10e, a supporting member 20e, a gas supply member 30e, a plasma source 40e and a heater 50e.

The substrate processing apparatus 1e may perform two different processes on the substrate S. The substrate processing apparatus 1e may sequentially perform two different processes on the substrate S. The substrate processing apparatus 1e may perform an etching process and an annealing process on the substrate S. The substrate processing apparatus 1e may perform an atomic layer etching process and a hydrogen plasma annealing process on the substrate S.

The plasma source 40e may excite the gas into a plasma state inside the chamber 10e. The plasma source 40e may include a plasma excite member 41e and a magnetron 42e.

The plasma excite member 41e may provide an energy for the plasma excitation inside the chamber 10e. The plasma excite member 41e may be provided as a flat plate structure with a slot hole 410e disposed therein. For example, the plasma excite member 41e may have a disk structure, and a plurality of slot holes 410e may be disposed. The slot holes 410e provide a passage for microwaves to pass through. The plasma excite member 41e may be embedded within the upper wall of the chamber 10e. On the upper wall of the chamber 10e, a transparent window 100e may be disposed below the plasma excite member 41e. The transparent window 100e may include a dielectric material. For example, the transmission window 100e may include alumina, quartz, etc.

The magnetron 42e may generate microwaves. The magnetron 42e may be connected to the chamber 10e via a waveguide 420e. Microwaves generated in the magnetron 42e may travel through the waveguide 420e and then be transmitted into the interior of the chamber 10e via the plasma excite member 41e. For example, an antenna rod 421e may be disposed inside the waveguide 420e. The antenna rod 421e may have extend in the vertical direction. The upper portion of the antenna rod 421e may be fixed to the waveguide 420e, and the lower portion of the antenna rod 421e may be fixed by an insertion at the center of the plasma excite member 41e. The antenna rod 421e may propagate microwaves to the plasma excite member 41e.

The remaining structure of the substrate processing apparatus 1e and the control of the substrate processing apparatus 1e are the same as or similar to those described above, and thus repeated descriptions are omitted.

FIG. 15 is a diagram illustrating a substrate processing apparatus according to one or more embodiments.

Referring to FIG. 15, a substrate processing apparatus 1f according to one or more embodiments may include a chamber 10f, a supporting member 20f, a gas supply member 30f, a plasma source 40f and a heater 50f.

The substrate processing apparatus 1f may perform two different processes on the substrate S. The substrate processing apparatus 1f may sequentially perform two different processes on the substrate S. The substrate processing apparatus 1f may perform an etching process and annealing process on the substrate S. The substrate processing apparatus 1f may perform an atomic layer etching process and a hydrogen plasma annealing process on the substrate S.

The plasma source 40f may supply a gas excited in a plasma state into the interior of the chamber 10f. That is, the plasma source 40f may include a structure for exciting a gas into a plasma state. Accordingly, the plasma source 40f may excite a gas into a plasma state and then discharge the gas to the outside. The plasma source 40f may be connected to the chamber 10f. For example, the plasma source 40f may be connected to the upper portion of the chamber 10f.

The plasma source 40f may excite the process gas into a plasma state and then supply it to the chamber 10f. Additionally, the plasma source 40f may supply at least one of the precursor gas and reactant gas to the chamber 10f after exciting it into a plasma state.

That is, the plasma source 40f may be controlled to supply the process gas to the chamber 10f after the gas has been excited to a plasma state during the annealing process. Additionally, the plasma source 40f may be controlled to supply the precursor gas to the chamber 10f after exciting the gas into a plasma state in the first period P1 of the etching process, and to supply the process gas to the chamber 10f after exciting the gas into a plasma state in the annealing process. Additionally, the plasma source 40f may be controlled to supply the reactant gas to the chamber 10f after the gas is excited to a plasma state in the third period P3f of the etching process, and to supply the process gas to the chamber 10f after the gas is excited to a plasma state in the annealing process. Additionally, the plasma source 40f may be controlled to supply a precursor gas to the chamber 10f after the gas is excited to a plasma state in the first period P1 of the etching process, to supply a reactant gas to the chamber 10f after the gas is excited to a plasma state in the third period P3 of the etching process, and to supply a process gas to the chamber 10f after the gas is excited to a plasma state in the annealing process.

FIG. 15 illustrates an example in which the precursor supply member 31f, the reactant supply member 32f, and the purge gas supply member 33f are connected to the chamber 10f, and the plasma source 40f excites the process gas into a plasma state and then supplies it to the chamber 10f.

The remaining structure of the substrate processing apparatus 1f and the control of the substrate processing apparatus 1f are the same as or similar to those described above, and thus repeated descriptions are omitted.

At least one of the devices, units, components, modules, units, or the like represented by a block or an equivalent indication in the above embodiments including may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A substrate processing apparatus comprising:
a chamber;
a heater;
a supporting member inside the chamber and configured to support a substrate, the supporting member comprising a lift pin that is movable in a vertical direction and is configured to move the substrate vertically with respect to the heater;
a plasma source configured to excite gas inside the chamber to into a plasma state for an annealing process; and
a gas supply member configured to supply gas into the chamber for a substrate processing process.

2. The substrate processing apparatus of claim 1, wherein the gas supply member comprises:
a precursor supply member configured to supply a precursor gas into the chamber;
a reactant supply member configured to supply a reactant gas into the chamber;
and a purge gas supply member configured to supply a purge gas into the chamber.

3. The substrate processing apparatus of claim 2, wherein the gas supply member further comprises a process gas supply member configured to supply a process gas for the annealing process into the chamber.

4. The substrate processing apparatus of claim 3, wherein the process gas comprises a hydrogen gas.

5. The substrate processing apparatus of claim 1, wherein the plasma source comprises:
a plasma excite member outside the chamber and having an antenna structure; and
a source power supply connected to the plasma excite member and configured to provide electric power.

6. The substrate processing apparatus of claim 5, wherein the heater is inside the chamber.

7. The substrate processing apparatus of claim 5, wherein the heater is outside the chamber.

8. The substrate processing apparatus of claim 1, wherein the plasma source comprises:
a plasma excite member with a lower surface facing an interior of the chamber; and
a source power supply connected to the plasma excite member or the supporting member and configured to provide electric power.

9. The substrate processing apparatus of claim 1, further comprising a waveguide,
wherein the plasma source comprises:
a magnetron configured to generate microwaves and connected to the chamber through the waveguide;
an electron coil disposed at an outer circumference of the chamber; and
a source power supply connected to the electron coil and configured to provide electric power.

10. The substrate processing apparatus of claim 1, further comprising a waveguide, wherein the plasma source comprises:
a plasma excite member within an upper wall of the chamber and comprising a passage through which microwaves pass; and
a magnetron connected to the chamber through the waveguide and configured to generate microwaves.

11. The substrate processing apparatus of claim 1, wherein the heater comprises a plurality of sub-heaters spaced apart from each other.

12. The substrate processing apparatus of claim 1, further comprising a chiller and a refrigerant path,
wherein the refrigerant path is inside the supporting member.

13. The substrate processing apparatus of claim 12, wherein the refrigerant path comprises a plurality of sub-refrigerant paths that are spaced apart from each other.

14. The substrate processing apparatus of claim 1, further comprising:
a lift pin driving member connected to the lift pin and configured to provide power to move the lift pin in the vertical direction; and
a controller configured to control the lift pin driving member to move the lift pin in the vertical direction,
wherein the controller is configured to move the lift pin such than an upper end of the lift pin is positioned above an upper surface of the supporting member when the heater heats the substrate.

15. A substrate processing apparatus comprising:
a chamber;
a heater;
a supporting member inside the chamber and configured to support a substrate, the supporting member comprising a lift pin that is movable ion a vertical direction and I configured to move the substrate vertically with respect to the heater;
a purge gas supply member configured to supply a purge gas for an atomic layer etching into the chamber; and
a plasma source configured to excite a process gas for an annealing process into a plasma state and supply the process gas excited into the plasma state to the chamber.

16. The substrate processing apparatus of claim 15, further comprising:
a lift pin driving member connected to the lift pin and configured to provide power to move the lift pin in the vertical direction; and
a controller configured to control the lift pin driving member to move the lift pin in the vertical direction,
wherein the controller is configured to move the lift pin such that an upper end of the lift pin is positioned above an upper surface of the supporting member when the process gas excited in the plasma state is supplied to the chamber and the heater heats the substrate.

17. A substrate processing apparatus comprising:
a chamber;
a heater;
a supporting member inside the chamber and configured to support a substrate, the supporting member comprising a lift pin that is movable in a vertical direction and is configured to move the substrate vertically with respect to the heater;
a plasma source configured to excite gas inside the chamber to into a plasma state for an annealing process;
a precursor supply member configured to supply a precursor gas into the chamber;
a reactant supply member configured to supply a reactant gas into the chamber;
a purge gas supply member configured to supply a purge gas into the chamber;
a process gas supply member configured to supply a process gas for the annealing process into the chamber;
a lift pin driving member connected to the lift pin and configured to provide power to move the lift pin in the vertical direction; and
a controller configured to control the heater when the process gas is supplied into the chamber and control the lift pin driving member to move an upper end of the lift pin vertically above an upper surface of the supporting member by a predetermined annealing heating height.

18. The substrate processing apparatus of claim 17, wherein the heater faces the supporting member.

19. The substrate processing apparatus of claim 17, wherein the controller is further configured to control the heater when the reactant gas is supplied into the chamber and control the lift pin driving member to move the upper end of the lift pin vertically above the upper surface of the supporting member by a predetermined etching heating height.

20. The substrate processing apparatus of claim 19, wherein the predetermined annealing heating height is greater than the predetermined etching heating height.
